(19) United States
(12) Patent Application Publication
(10) Pub. No.: US 2020/0075642 A1
(43) Pub. Date: Mar. 5, 2020

(54) METHOD FOR MANUFACTURING ACTIVE ARRAY SWITCH

(71) Applicant: HKC Corporation Ltd., Guangdong (CN)

(72) Inventor: Huailiang HE, Guangdong (CN)

(21) Appl. No.: 15/739,312

(22) PCT Filed: Sep. 22, 2017
(86) PCT No.: PCT/CN2017/102868

§ 371 Date: Dec. 22, 2017

(30) Foreign Application Priority Data
Sep. 15, 2017 (CN) 201710835243.0

(51) Int. Cl. H01L 27/12

(52) U.S. Cl. CPC H01L 27/1288; H01L 27/1218; H01L 27/1222

(57) ABSTRACT

This application provides a method for manufacturing an active array switch, including: forming a gate pattern on a substrate, and then forming a gate insulation layer to cover the gate pattern; forming a semiconductor layer on the gate insulation layer, and forming a first photoresist layer having a plurality of thicknesses on the semiconductor layer, where a thickness of the first photoresist layer above the middle part of the gate pattern is greater than a thicknesses of the first photoresist layer above the two sides of the gate pattern; removing the semiconductor layer, to form a semiconductor pattern; performing a dry etching process on the first photoresist layer; forming a source and a drain on the semiconductor pattern and the gate insulation layer, and removing the entire photoresist layer above the source and the drain and the entire photoresist layer above the middle part of the gate pattern.

### BACKGROUND

### Technical Field

This application relates to a method for manufacturing an active array switch, and in particular, to a method for manufacturing an active array switch by using which a semiconductor layer can be effectively protected from being affected by source and drain etching solutions.

### Related Art

Currently, a semiconductor layer in an active array switch driving a display panel mainly includes an amorphous silicon (a-Si) semiconductor layer, an oxide semiconductor layer, a polycrystalline silicon (Poly-Si) semiconductor layer, and the like. Compared with an a-Si semiconductor, an oxide semiconductor has higher mobility and a lower electric leakage rate. Although having higher mobility, a Poly-Si active array switch is not applicable to the current production line of a mainstream product as a result of relatively high costs.

A commonly used structure of an active array switch with an oxide semiconductor includes an etch stop layer (ESL) structure, a back channel etch (BCE) structure, a co-planner self-align top gate structure, a dual gate structure, and the like. Although it is easier to process an ESL structure, a photolithography process needs to be performed for a plurality of times on the ESL structure. Therefore, a BCE structure is preferred for massive and low-cost production.

However, when processing an active array switch with a BCE structure, one of the problems is that an oxide semiconductor layer may be permanently damaged by source and drain etching solutions, affecting electric performance of the active array switch, and even directly leading to that the active array switch does not have semiconductor characteristics.

### SUMMARY

An objective of this application is to provide a method for manufacturing an active array switch, and in particular, to provide a method for manufacturing an active array switch by using which a semiconductor layer can be effectively protected from being affected by source and drain etching solutions.

In recent years, due to the progress of the semiconductor process technologies, manufacturing of active array switches is increasingly easier and faster. Active array switches are widely applied to electronic products such as computer chip, mobile phone chip, and active array switch liquid crystal display (thin film transistor liquid crystal display, TFT LCD). Using an active array switch liquid crystal display as an example, the active array switch is used for charging or discharging a storage capacitor.

Generally, active array switches may be categorized as amorphous silicon (Amorphous Silicon Transistor) active array switches and polycrystalline silicon (Low Temperature Polycrystalline Transistor) active array switches according to the materials of semiconductor layers. Meanwhile, to cater to the dramatic increase of demand on liquid crystal displays in the market, more have been invested into research and development of new active array switch technologies. An active array switch with a semiconductor layer made of metal oxide such as zinc oxide (ZnO) has been invented. Electric performance of such an active array switch has caught up with the a-Si active array switches, and component performance of such an active array switch is relatively good. However, using the active array switch with a semiconductor layer made of ZnO as an example, when processing a source and a drain subsequently, ZnO is prone to be damaged by materials such as plasma, an etching solution and a photoresist stripping solution, leading to change of thin film performance of the semiconductor layer, and further, affecting component performance of the active array switch.

Therefore, this application provides a method for manufacturing an active array switch, comprising: forming a first metal layer on a substrate, and patterning the first metal layer, to form a gate pattern; forming a gate insulation layer on the substrate, to cover the gate pattern; forming a semiconductor layer on the gate insulation layer, forming a first photoresist layer having a plurality of thicknesses on the semiconductor layer, where a thickness of the first photoresist layer above the middle part of the gate pattern is greater than a thicknesses of the first photoresist layer above the two sides of the gate pattern; removing a part of the semiconductor layer, to form a semiconductor pattern; performing a dry etching process on the first photoresist layer, to remove the thicknesses of the first photoresist layer above the two sides of the gate pattern and make the thickness, of the first photoresist layer, left after the dry etching and above the middle part of the gate pattern still cover a part of the semiconductor pattern; sequentially forming a second metal layer and a second photoresist layer on the semiconductor pattern and the gate insulation layer; patterning the second photoresist layer, to form a source pattern and a drain pattern; patterning the second metal layer, to form a source and a drain; and removing the entire second photoresist layer above the source and the drain, and removing the entire first photoresist layer above the gate pattern.

In an embodiment of this application, the step of forming the first photoresist layer having a plurality of thicknesses comprises: forming a photosensitive material layer on the semiconductor layer, performing an exposure process on the photosensitive material layer by using a half-tone photomask, and performing a development process.

In an embodiment of this application, the step of forming the first photoresist layer having a plurality of thicknesses comprises: forming a photosensitive material layer on the semiconductor layer, performing an exposure process on the photosensitive material layer by using a gray-tone photomask, and performing a development process.

In an embodiment of this application, the semiconductor layer is a metal oxide semiconductor layer, where metal of the metal oxide semiconductor layer comprises elements from group II to group VI and groups comprising compounds of these elements.

In an embodiment of this application, the metal oxide semiconductor layer is further doped with one or more elements selected from alkaline-earth metal, group IIIA, group VA, group VIA or a group comprising transition metal.

In an embodiment of this application, an insulation material layer is formed between the semiconductor layer and the first photoresist layer.

In the foregoing embodiment of this application, the insulation material layer is an inorganic insulation material layer such as a silicon oxide layer or a silicon nitride layer.

In the foregoing embodiment of this application, the insulation material layer is an organic insulation material layer such as a polymethyl methacrylate layer or a polyvinyl phenol layer.

Further, the objective of this application may be achieved and the technical problem of this application may be resolved by using the following technical solutions. This application provides a method for manufacturing an active array switch, comprising: forming a first metal layer on a substrate, and patterning the first metal layer, to form a gate pattern; forming a gate insulation layer on the substrate, to cover the gate pattern; forming a semiconductor layer on the gate insulation layer, forming an insulation material layer on the semiconductor layer, forming a photosensitive material layer on the insulation material layer; performing an exposure process on the photosensitive material layer by using a photomask; forming a first photoresist layer having a plurality of thicknesses by means of a development process, where a thickness of the first photoresist layer above the middle part of the gate pattern is greater than a thicknesses of the first photoresist layer above the two sides of the gate pattern; removing a part of the semiconductor layer, to form a semiconductor pattern; performing a dry etching process on the first photoresist layer, to remove the thicknesses of the first photoresist layer above the two sides of the gate pattern and leave the part of the first photoresist layer above the middle part of the gate pattern to cover a part of the semiconductor pattern; sequentially forming a second metal layer and a second photoresist layer on the semiconductor pattern and the gate insulation layer; patterning the second photoresist layer, to form a source pattern and a drain pattern; patterning the second metal layer, to form a source and a drain; and removing the entire second photoresist layer above the source and the drain, and removing the entire first photoresist layer above the gate pattern.

Due to the improvement made in this application, during a BCE process of an active array switch, a first photoresist layer on a semiconductor layer above a gate pattern (at a TFT back channel) may be reserved, and then a normal film forming etching process may be performed on a source and a drain, to remove a second photoresist layer above the source and the drain while dissolving the first photoresist layer above the gate pattern. By means of this method, a semiconductor pattern at a TFT back channel is effectively protected from being affected by source and drain etching solutions, thereby achieving stable electric performance of the active array switch.

### BRIEF DESCRIPTION OF THE DRAWINGS

FIG. 1A is a schematic diagram of film forming of a semiconductor according to an embodiment of this application;

FIG. 1B is a schematic diagram of formation of a first photoresist layer according to an embodiment of this application;

FIG. 1C is a schematic diagram of formation of a semiconductor pattern according to an embodiment of this application;

FIG. 1D is a schematic diagram of performing a dry etching process according to an embodiment of this application;

FIG. 1E is a schematic diagram of formation of a second metal layer and a second photoresist layer according to an embodiment of this application;

FIG. 1F is a schematic diagram of removing all photoresist layers according to an embodiment of this application;

FIG. 1G is a flowchart of a method for manufacturing an active array switch according to an embodiment of this application;

FIG. 2 is a schematic diagram of formation of an insulation material layer according to another embodiment of this application; and

FIG. 3 is a flowchart of a method for manufacturing an active array switch according to another embodiment of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is located on the top based on a gravity direction.

To further describe the technical measures taken in this application to achieve the intended application objective and effects thereof, specific implementations, structures, features, and effects of a method for manufacturing an active array switch provided according to this application are described below in detail with reference to the drawings and preferred embodiments.

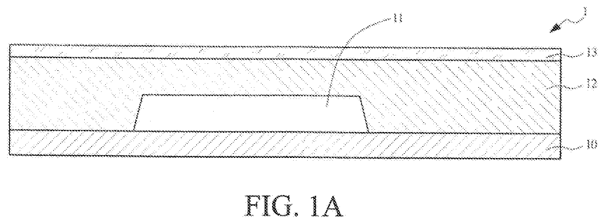

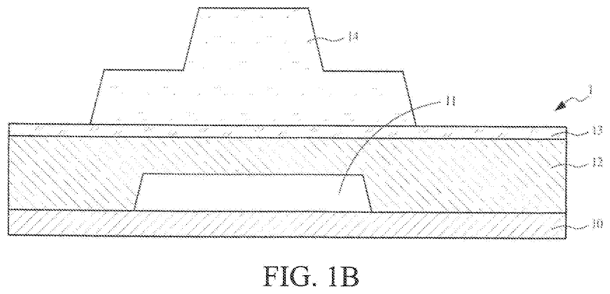

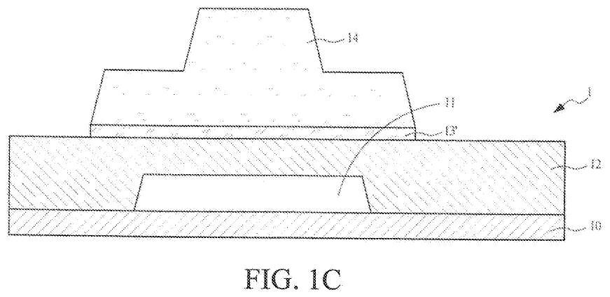

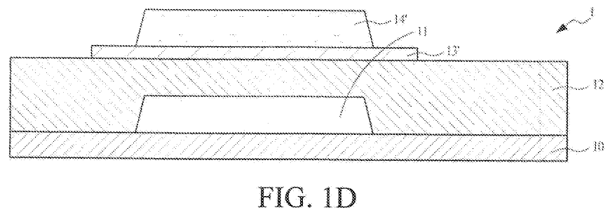

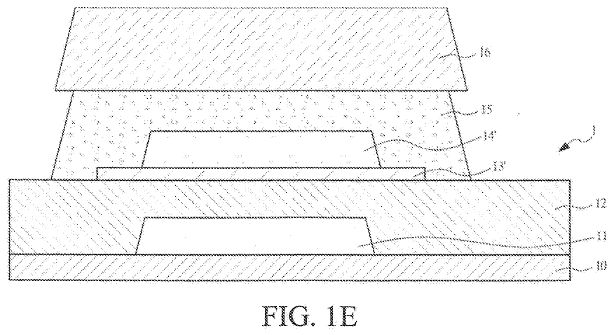

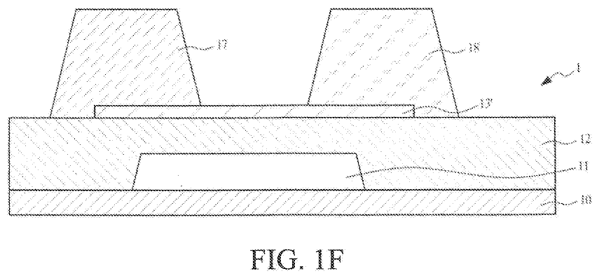

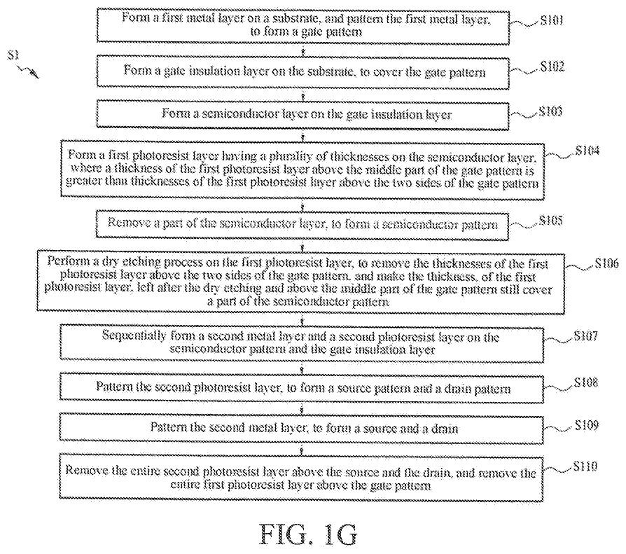

This application provides a method for manufacturing an active array switch, in which a first photoresist layer covers a semiconductor layer, to protect a semiconductor pattern formed by the semiconductor layer. The method for manufacturing an active array switch provided in this application includes the following steps. Referring to FIG. 1A to FIG. 1G, a method for manufacturing an active array switch 1 provided in this application is first shown in FIG. 1A. A first metal layer is formed on a substrate 10, and the first metal layer is patterned, to form a plurality of gate patterns 11. Then, a gate insulation layer 12 is formed on the substrate 10, to cover the gate pattern 11, and then a semiconductor layer 13 is formed on the gate insulation layer 12.

In an embodiment, the semiconductor layer 13 is a metal oxide semiconductor layer, where metal of the metal oxide semiconductor layer includes elements from group II to group VI and groups including compounds of these elements.

In the foregoing embodiment, the metal oxide semiconductor layer is further doped with one or more elements selected from alkaline-earth metal, group IIIA, group VA, group VIA or a group including transition metal.

Next, as shown in FIG. 1B, a first photoresist layer 14 having a plurality of thicknesses is formed on the semiconductor layer 13, where a thickness of the first photoresist layer 14 above the middle part of the gate pattern 11 is greater than a thicknesses of the first photoresist layer 14 above the two sides of the gate pattern 11.

In an embodiment, the step of forming the first photoresist layer 14 having a plurality of thicknesses includes: forming a photosensitive material layer on the semiconductor layer 13, performing an exposure process on the photosensitive material layer by using a half-tone photomask, and performing a development process.

In an embodiment, the step of forming the first photoresist layer 14 having a plurality of thicknesses includes: forming a photosensitive material layer on the semiconductor layer 13, performing an exposure process on the photosensitive material layer by using a gray-tone photomask, and performing a development process.

Next, as shown in FIG. 1C, a part of the semiconductor layer 13 is removed, to form a semiconductor pattern 13′.

Next, as shown in FIG. 1D, a dry etching process (such as plasma etching) is performed on the first photoresist layer 14, to remove the thicknesses of the first photoresist layer 14 above the two sides of the gate pattern 11, and make the thickness (the first photoresist layer 14), of the first photoresist layer 14, left after the dry etching and above the middle part of the gate pattern 11 still cover a part of the semiconductor pattern 13′.

Next, as shown in FIG. 1E, a second metal layer 15 and a second photoresist layer 16 are sequentially formed on the semiconductor pattern 13′ and the gate insulation layer 12, and the second photoresist layer 16 is patterned, to form a source pattern and a drain pattern.

Finally, as shown in FIG. 1F, the second metal layer 15 is patterned, to form a source 17 and a drain 18, and the entire second photoresist layer 16 above the source 17 and the drain 18 is removed, and the entire first photoresist layer 14′ above the gate pattern 11 is removed.

That is, this application provides a method S1 for manufacturing an active array switch, which includes the following steps:

Step S101: Form a first metal layer on a substrate, and pattern the first metal layer, to form a gate pattern.

Step S102: Form a gate insulation layer on the substrate, to cover the gate pattern.

Step S103: Form a semiconductor layer on the gate insulation layer.

Step S104: Form a first photoresist layer having a plurality of thicknesses on the semiconductor layer, where a thickness of the first photoresist layer above the middle part of the gate pattern is greater than a thicknesses of the first photoresist layer above the two sides of the gate pattern.

Step S105: Remove a part of the semiconductor layer, to form a semiconductor pattern.

Step S106: Perform a dry etching process on the first photoresist layer, to remove the thicknesses of the first photoresist layer above the two sides of the gate pattern and make the thickness, of the first photoresist layer, left after the dry etching and above the middle part of the gate pattern still cover a part of the semiconductor pattern.

Step S107: Sequentially form a second metal layer and a second photoresist layer on the semiconductor pattern and the gate insulation layer.

Step S108: Pattern the second photoresist layer, to form a source pattern and a drain pattern.

Step S109: Pattern the second metal layer, to form a source and a drain.

Step S110: Remove the entire second photoresist layer above the source and the drain, and remove the entire first photoresist layer above the gate pattern.

The manufacturing method is substantially as shown in FIG. 1A to FIG. 1F. The only difference is that an insulation material layer 19 is formed between the semiconductor layer 13 and the first photoresist layer 14.

That is, as shown in FIG. 1A, a first metal layer is formed on a substrate 10, and the first metal layer is patterned, to form a gate pattern 11. Then, a gate insulation layer 12 is formed on the substrate 10, to cover the gate pattern 11, and then a semiconductor layer 13 is formed on the gate insulation layer 12.

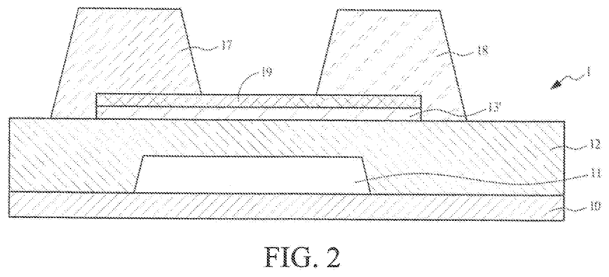

Next, an insulation material layer 19 (as shown in FIG. 2) is first formed on the semiconductor layer 13, to protect the metal semiconductor layer used in this application. The insulation material layer is an inorganic insulation material layer such as a silicon oxide layer or a silicon nitride layer, or may be an organic insulation material layer such as a polymethyl methacrylate layer or a polyvinyl phenol layer.

Next, as shown in FIG. 1B, a first photoresist layer 14 having a plurality of thicknesses is formed on the semiconductor layer 13, where a thickness of the first photoresist layer 14 above the middle part of the gate pattern 11 is greater than a thicknesses of the first photoresist layer 14 above the two sides of the gate pattern 11.

Next, as shown in FIG. 1C, a part of the semiconductor layer 13 is removed, to form a semiconductor pattern 13′.

Further, as shown in FIG. 1D, FIG. 1E and FIG. 1F, a dry etching process (such as plasma etching) is performed on the first photoresist layer 14, to remove the thicknesses of the first photoresist layer 14 above the two sides of the gate pattern 11 and make the thickness (the first photoresist layer 14′), of the first photoresist layer 14, left after the dry etching and above the middle part of the gate pattern 11 still cover a part of the semiconductor pattern 13′. A second metal layer 15 and a second photoresist layer 16 are sequentially formed on the semiconductor pattern 13′ and the gate insulation layer 12, and the second photoresist layer 16 is patterned, to form a source pattern and a drain pattern. Finally, the second metal layer 15 is patterned, to form a source 17 and a drain 18, and the entire second photoresist layer 16 above the source 17 and the drain 18 is removed, and the entire first photoresist layer 14′ above the gate pattern 11 is removed.

Finally, a structure shown in FIG. 2 is formed. That is, a gate pattern 11 is formed on a substrate 10. A gate insulation layer 12 is formed on the substrate 10 and the gate pattern 11, to cover the gate pattern 11. A semiconductor pattern 13′ is formed above the middle part of the gate pattern 11 due to masking of a photoresist layer. In addition, the semiconductor pattern 13′ is covered by an insulation material layer 19 made of an organic or inorganic material. A source 17 and a drain 18 are formed from a second metal layer above the two sides of the gate pattern 11.

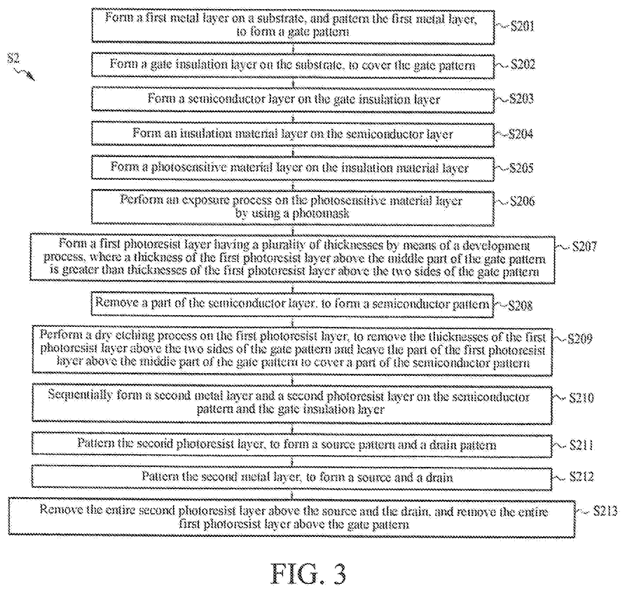

Further, the objective of this application may be achieved and the technical problem of this application may be resolved by using the procedures shown in FIG. 3. This application provides a method S2 for manufacturing an active array switch, which includes the following steps:

Step S201: Form a first metal layer on a substrate, and pattern the first metal layer, to form a gate pattern.

Step S202: Form a gate insulation layer on the substrate, to cover the gate pattern.

Step S203: Form a semiconductor layer on the gate insulation layer.

Step S204: Form an insulation material layer on the semiconductor layer.

Step S205: Form a photosensitive material layer on the insulation material layer.

Step S206: Perform an exposure process on the photosensitive material layer by using a photomask.

Step S207: Form a first photoresist layer having a plurality of thicknesses by means of a development process, where a thickness of the first photoresist layer above the middle part of the gate pattern is greater than a thicknesses of the first photoresist layer above the two sides of the gate pattern.

Step S208: Remove a part of the semiconductor layer, to form a semiconductor pattern.

Step S209: Perform a dry etching process on the first photoresist layer, to remove the thicknesses of the first photoresist layer above the two sides of the gate pattern and leave the part of the first photoresist layer above the middle part of the gate pattern to cover a part of the semiconductor pattern.

Step S210: Sequentially form a second metal layer and a second photoresist layer on the semiconductor pattern and the gate insulation layer.

Step S211: Pattern the second photoresist layer, to form a source pattern and a drain pattern.

Step S212: Pattern the second metal layer, to form a source and a drain.

Step S213: Remove the entire second photoresist layer above the source and the drain, and remove the entire first photoresist layer above the gate pattern.

Due to the improvement made in this application, during a BCE process of an active array switch 1, a first photoresist layer 14 on a semiconductor layer 13 above a gate pattern 11 (at a TFT back channel) may be reserved, and then a normal film forming etching process may be performed on a source and a drain, to remove a second photoresist layer 16 above the source and the drain while dissolving the first photoresist layer 14′ above the gate pattern 11. By means of this method, a semiconductor pattern 13′ at a TFT back channel is effectively protected from being affected by source and drain etching solutions, thereby achieving stable electric performance of the active array switch 1.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

The foregoing descriptions are merely embodiments of this application, and are not intended to limit this application in any form. Although this application has been disclosed above through the specific embodiments, the embodiments are not intended to limit this application. Any person skilled in the art can make some variations or modifications, which are equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A method for manufacturing an active array switch, comprising:
forming a first metal layer on a substrate, and patterning the first metal layer, to form a gate pattern;
forming a gate insulation layer on the substrate, to cover the gate pattern;
forming a semiconductor layer on the gate insulation layer;
forming a first photoresist layer having a plurality of thicknesses on the semiconductor layer, wherein a thickness of the first photoresist layer above the middle part of the gate pattern is greater than a thicknesses of the first photoresist layer above the two sides of the gate pattern;
removing a part of the semiconductor layer, to form a semiconductor pattern;
performing a dry etching process on the first photoresist layer, to remove the thicknesses of the first photoresist layer above the two sides of the gate pattern and leave the part of the first photoresist layer above the middle part of the gate pattern to cover a part of the semiconductor pattern;
sequentially forming a second metal layer and a second photoresist layer on the semiconductor pattern and the gate insulation layer;
patterning the second photoresist layer, to form a source pattern and a drain pattern;
patterning the second metal layer, to form a source and a drain; and
removing the entire second photoresist layer above the source and the drain, and removing the entire first photoresist layer above the gate pattern.

2. The method for manufacturing an active array switch according to claim 1, wherein the step of forming the first photoresist layer having a plurality of thicknesses comprises forming a photosensitive material layer on the semiconductor layer.

3. The method for manufacturing an active array switch according to claim 2, comprising: performing an exposure process on the photosensitive material layer by using a half-tone photomask, and performing a development process.

4. The method for manufacturing an active array switch according to claim 2, comprising: performing an exposure process on the photosensitive material layer by using a gray-tone photomask, and performing a development process.

5. The method for manufacturing an active array switch according to claim 1, wherein the semiconductor layer is a metal oxide semiconductor layer.

6. The method for manufacturing an active array switch according to claim 5, wherein metal of the metal oxide semiconductor layer comprises elements from group II to group VI and groups comprising compounds of these elements.

7. The method for manufacturing an active array switch according to claim 6, wherein the metal oxide semiconductor layer is further doped with an alkaline-earth metal element.

8. The method for manufacturing an active array switch according to claim 6, wherein the metal oxide semiconductor layer is further doped with a group IIIA element.

9. The method for manufacturing an active array switch according to claim 6, wherein the metal oxide semiconductor layer is further doped with a group VA element.

10. The method for manufacturing an active array switch according to claim 6, wherein the metal oxide semiconductor layer is further doped with a group VIA element.

11. The method for manufacturing an active array switch according to claim 6, wherein the metal oxide semiconductor layer is further doped with one element selected from a group comprising transition metal.

12. The method for manufacturing an active array switch according to claim 6, wherein the metal oxide semiconductor layer is further doped with a plurality of elements selected from a group comprising transition metal.

13. The method for manufacturing an active array switch according to claim 1, wherein an insulation material layer is formed between the semiconductor layer and the first photoresist layer.

14. The method for manufacturing an active array switch according to claim 13, wherein the insulation material layer is an inorganic insulation material layer.

15. The method for manufacturing an active array switch according to claim 14, wherein the inorganic insulation material layer is made of silicon oxide.

16. The method for manufacturing an active array switch according to claim 14, wherein the inorganic insulation material layer is made of silicon nitride.

17. The method for manufacturing an active array switch according to claim 13, wherein the insulation material layer is an organic insulation material layer.

18. The method for manufacturing an active array switch according to claim 17, wherein the organic insulation material layer is made of polymethyl methacrylate.

19. The method for manufacturing an active array switch according to claim 17, wherein the organic insulation material layer is made of polyvinyl phenol.

20. A method for manufacturing an active array switch, comprising:
forming a first metal layer on a substrate, and patterning the first metal layer, to form a gate pattern;
forming a gate insulation layer on the substrate, to cover the gate pattern;
forming a semiconductor layer on the gate insulation layer,
forming an insulation material layer on the semiconductor layer;
forming a photosensitive material layer on the insulation material layer;
performing an exposure process on the photosensitive material layer by using a photomask;
forming a first photoresist layer having a plurality of thicknesses by means of a development process, wherein a thickness of the first photoresist layer above the middle part of the gate pattern is greater than a thickness of the first photoresist layer above the two sides of the gate pattern;
removing a part of the semiconductor layer, to form a semiconductor pattern;
performing a dry etching process on the first photoresist layer, to remove the thicknesses of the first photoresist layer above the two sides of the gate pattern and leave the part of the first photoresist layer above the middle part of the gate pattern to cover a part of the semiconductor pattern;
sequentially forming a second metal layer and a second photoresist layer on the semiconductor pattern and the gate insulation layer,
patterning the second photoresist layer, to form a source pattern and a drain pattern;
patterning the second metal layer, to form a source and a drain; and
removing the entire second photoresist layer above the source and the drain, and removing the entire first photoresist layer above the gate pattern.
